(19) United States
(12) Patent Application Publication
(10) Pub. No.: US 2026/0011651 A1
(43) Pub. Date: Jan. 8, 2026

(54) SEMICONDUCTOR PACKAGE STRUCTURE AND MANUFACTURING METHOD THEREOF

(71) Applicant: Powertech Technology Inc., Hsinchu County (TW)

(72) Inventors: Shang-Yu Chang Chien, Hsinchu County (TW); Chih Hao Chen, Hsinchu County (TW)

(73) Assignee: Powertech Technology Inc., Hsinchu County (TW)

(21) Appl. No.: 19/031,146

(22) Filed: Jan. 17, 2025

(30) Foreign Application Priority Data
Jul. 5, 2024 (TW) 113125392

(51) Int. Cl. H01L 23/538; H01L 21/48; H01L 23/00; H01L 23/498; H01L 25/18

(52) U.S. Cl. CPC H01L 23/5386; H01L 21/4853; H01L 23/49816; H01L 23/49866; H01L 24/13; H01L 24/16; H01L 25/18; H01L 2224/13111; H01L 2224/13139; H01L 2224/13147; H01L 2224/13155; H01L 2224/16227

(57) ABSTRACT

A semiconductor package structure includes a redistribution structure layer, at least one chip, an encapsulant, and multiple solder balls. The redistribution structure layer includes multiple first connectors located on a first side. Each first connector includes a connecting pad, a soldering pad, and multiple conductive blind holes located between the connecting pad and the soldering pad. The conductive blind holes are disposed separately from each other and connect the connecting pad and the soldering pad. The chip is disposed on a second side of the redistribution structure layer and electrically connected to the redistribution structure layer. The encapsulant is disposed on the second side and at least covers the chip and the second side. The solder balls are disposed on the first side of the redistribution structure layer and electrically connected to the redistribution structure layer. The solder balls are respectively connected to the connecting pad of each first connector.

### CROSS-REFERENCE TO RELATED APPLICATION

This application claims the priority benefit of Taiwan application serial no. 113125392, filed on Jul. 5, 2024. The entirety of the above-mentioned patent application is hereby incorporated by reference herein and made a part of this specification.

### BACKGROUND

### Technical Field

The disclosure relates to a package structure and a manufacturing method thereof, and in particular to a semiconductor package structure and a manufacturing method thereof.

### Description of Related Art

As advanced packaging technology continues to develop, fine pitch bumps have become an important indicator of factory capabilities. In order to increase the density of components per unit volume, stacking technology plays a very important role not only at the wafer level but also at the packaging level. In view of the growing market demand, many fan-out packaging technologies are currently launched. In the manufacturing process of fan-out packages, flip chip bonding is mainly performed through fine pitch bumps. In the related art, when manufacturing a redistribution structure layer, usually the operation is to connect a solder ball connecting pad and a soldering pad through a conductive blind hole. However, due to factors such as large holes and variations in the hole filling process, it is easy to cause problems of subsequent film layers (such as dielectric layers and/or circuits) having poor flatness after the conductive blind hole is formed, thereby the structural reliability of the subsequently formed fine pitch bumps.

### SUMMARY

The disclosure provides a semiconductor package structure, which has better structural reliability.

The disclosure further provides a manufacturing method of a semiconductor package structure, which is used to manufacture the semiconductor package structure.

The semiconductor package structure of the disclosure includes a redistribution structure layer, at least one chip, an encapsulant, and a plurality of solder balls. The redistribution structure layer has a first side and a second side opposite to each other, and includes multiple first connectors located on the first side. Each first connector includes a connecting pad, a soldering pad, and multiple conductive blind holes located between the connecting pad and the soldering pad. The conductive blind holes are disposed separately from each other and connected to the connecting pad and the soldering pad. At least one chip is disposed on the second side of the redistribution structure layer and is electrically connected to the redistribution structure layer. An encapsulant is disposed on the second side of the redistribution structure layer, and covers at least one chip and the second side of the redistribution structure layer. The solder ball is disposed on the first side of the redistribution structure layer and is electrically connected to the redistribution structure layer. The solder balls are respectively connected to the connecting pads of the respective first connectors.

In an embodiment of the disclosure, the at least one chip has at least one active surface and at least one back opposite to each other. The at least one active surface faces the second side of the redistribution structure layer, and the encapsulant is exposed outside the at least one back.

In an embodiment of the disclosure, the redistribution structure layer further includes a plurality of second connectors located on the second side. At least one chip is electrically connected to the second connector.

In an embodiment of the disclosure, each of the second connectors includes a chip connecting pad, a nickel layer, and a gold layer. The chip connecting pad has a top surface and a surrounding surface connected to the top surface. The nickel layer covers the top surface and the surrounding surface of the chip connecting pad. The gold layer covers the nickel layer on the top surface of the chip connecting pad.

In an embodiment of the disclosure, the disposition density of the second connectors is greater than the disposition density of the first connectors.

In an embodiment of the disclosure, the semiconductor package structure further includes a plurality of third connectors and a plurality of solders. The third connector is disposed between at least one chip and the second connector of the redistribution structure layer. The solder is located between the third connector and the second connector of the redistribution structure layer.

In an embodiment of the disclosure, each of the third connectors includes a copper/tin-silver micro-bump, a copper/nickel/tin-silver micro-bump, or a nickel/tin-silver micro-bump.

In an embodiment of the disclosure, the semiconductor package structure further includes an underfill disposed between at least one chip and the second connector of the redistribution structure layer and covering the second connector and the third connector.

In an embodiment of the disclosure, the semiconductor package structure further includes at least one passive component disposed on the second side of the redistribution structure layer and electrically connected to the redistribution structure layer, in which the encapsulant covers at least one passive component.

In an embodiment of the disclosure, the redistribution structure layer further includes a dielectric layer. The dielectric layer has a first surface and a second surface opposite to each other and multiple openings. The soldering pad of each first connector is disposed on the first surface, and the connecting pad of each first connector is embedded in the second surface. The openings are separated from each other and extend from the first surface to the second surface to expose a portion of the connecting pads. The conductive blind holes of the respective first connectors are respectively located in the openings and electrically connected to the soldering pads and the connecting pads of the respective first connectors.

In an embodiment of the disclosure, viewed from above, the shape of each opening of the dielectric layer includes a circle, an ellipse, or a polygon.

In an embodiment of the disclosure, the orthographic projection area of the soldering pad of each of the first connectors on the dielectric layer is overlapped with and larger than the orthographic projection area of the connecting pad on the dielectric layer.

In an embodiment of the disclosure, at least one active surface of the at least one chip is parallel to the redistribution structure layer.

In an embodiment of the disclosure, the quantity of the conductive blind holes of each first connector is two or more.

In an embodiment of the disclosure, the redistribution structure layer includes a fan-out redistribution structure layer.

The manufacturing method of the semiconductor package structure of the disclosure includes the following steps. A carrier board and a redistribution structure layer formed on the carrier board are provided. The redistribution structure layer has a first side and a second side opposite to each other, and includes multiple first connectors located on the first side. The first side of the redistribution structure layer is disposed on the carrier board. Each first connector includes a connecting pad, a soldering pad, and multiple conductive blind holes between the connecting pad and the soldering pad. The conductive blind holes are disposed separately from each other and connected to the connecting pad and the soldering pad. At least one chip is disposed on the second side of the redistribution structure layer. The at least one chip is electrically connected to the redistribution structure layer. An encapsulant is formed on the second side of the redistribution structure layer. The encapsulant covers the at least one chip and the second side of the redistribution structure layer. The carrier board is removed to expose the first side of the redistribution structure layer. Multiple solder balls are formed on the first side of the redistribution structure layer and are electrically connected to the redistribution structure layer. The solder balls are respectively connected to the connecting pads of the respective first connectors.

In an embodiment of the disclosure, before disposing the at least one chip on the second side of the redistribution structure layer, the following steps are further included. A seed layer is formed on the second side of the redistribution structure layer. A patterned photoresist layer is formed on the seed layer. The patterned photoresist layer has multiple first openings, and the first openings respectively expose a first portion of the seed layer. The patterned photoresist layer is used as the electroplating mask, and by electroplating, multiple chips connecting pads are formed on the first portion of the seed layer exposed by the first openings. Each first opening exposes a top surface of each chip connecting pad. A portion of the patterned photoresist layer located around each chip connecting pad is removed to form a photoresist layer having multiple second openings. Each second opening exposes the top surface of each chip connecting pad, a surrounding surface connected to the top surface, and a second portion of the seed layer. The photoresist layer is used as the electroplating mask, and by electroplating, a nickel layer is formed on the top surface and the surrounding surface of each chip connecting pad and the second portion of the seed layer exposed by each second opening. The photoresist layer is used as the electroplating mask, and by electroplating, a gold layer is formed on the nickel layer. Each chip connecting pad, the nickel layer covering the top surface and the surrounding surface of the chip connecting pad, and the gold layer covering the nickel layer located on the top surface of the chip connecting pad define a second connector. The photoresist layer and the seed layer therebelow are removed.

In an embodiment of the disclosure, methods for removing the portion of the patterned photoresist layer located around each chip connecting pad includes an exposure process and a development process, an over-development process, or a plasma dry etching process.

In an embodiment of the disclosure, the manufacturing method of the semiconductor package structure further includes the following. Before the encapsulant is formed on the second side of the redistribution structure layer, at least one passive component is disposed on the second side of the redistribution structure layer. The at least one passive component is electrically connected to the redistribution structure layer.

In an embodiment of the disclosure, after the solder ball is formed on the first side of the redistribution structure layer, a dicing and singulation process is performed.

Based on the above, in the semiconductor package structure of the disclosure, the first connector of the redistribution structure layer includes a connecting pad, a soldering pad, and multiple conductive blind holes located between the connecting pad and the soldering pad, in which the conductive blind holes are disposed separately from each other and connected to the connecting pad and the soldering pad. Through the manner of the conductive blind holes connecting the connecting pad and the soldering pad, the subsequent film layer formed thereon can be relatively flat, so the overall redistribution structure layer can have better structural flatness, thereby the semiconductor package structure of the disclosure can have better structural reliability.

In order to make the above-mentioned features and advantages of the disclosure more comprehensible, embodiments are given below and described in detail with reference to the accompanying drawings.

### BRIEF DESCRIPTION OF THE DRAWINGS

FIG. 1A to FIG. 1J are schematic cross-sectional views of a manufacturing method of a semiconductor package structure according to an embodiment of the disclosure.

FIG. 1K is a top view of the first connector in FIG. 1J.

### DESCRIPTION OF THE EMBODIMENTS

The embodiments of the disclosure may be understood together with the drawings, and the drawings of the disclosure are also regarded as a portion of the disclosure description. It is to be understood that the drawings of the disclosure are not drawn to scale and, in fact, the dimensions of elements may be arbitrarily enlarged or reduced in order to clearly illustrate the features of the disclosure.

Unless expressly stated otherwise, directional terms used herein (for example, up, down, left, right, front, back, top, bottom) are used by reference only to the drawings and are not intended to imply absolute orientation. Furthermore, any method described herein is in no way intended to be construed as requiring that the steps thereof be performed in a particular order unless expressly stated otherwise.

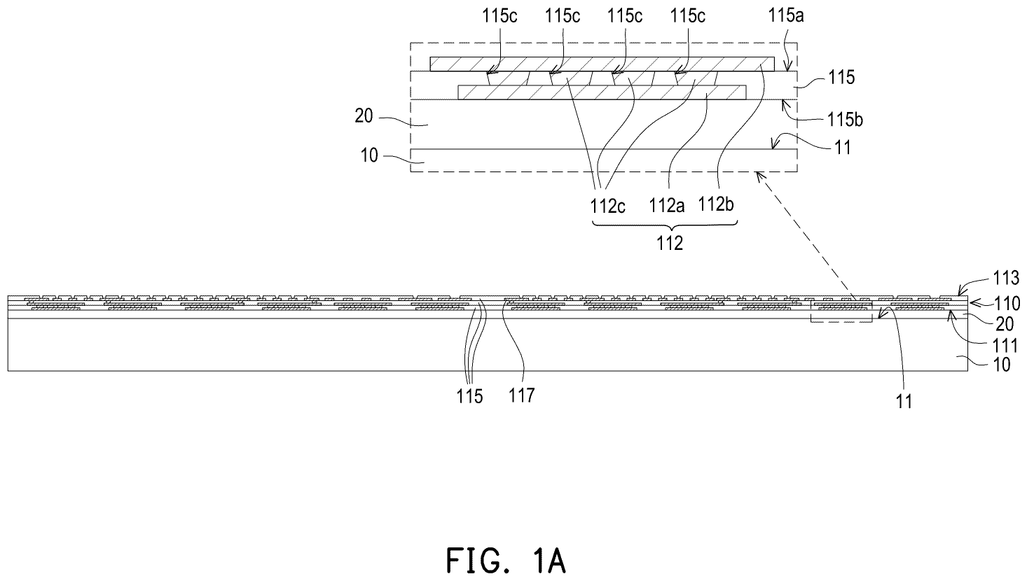

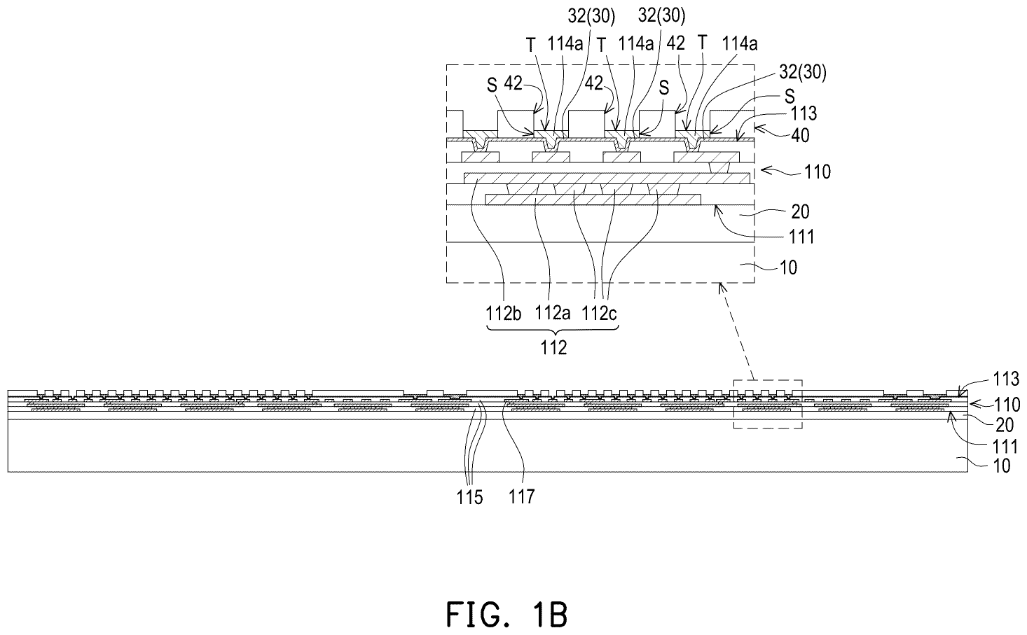

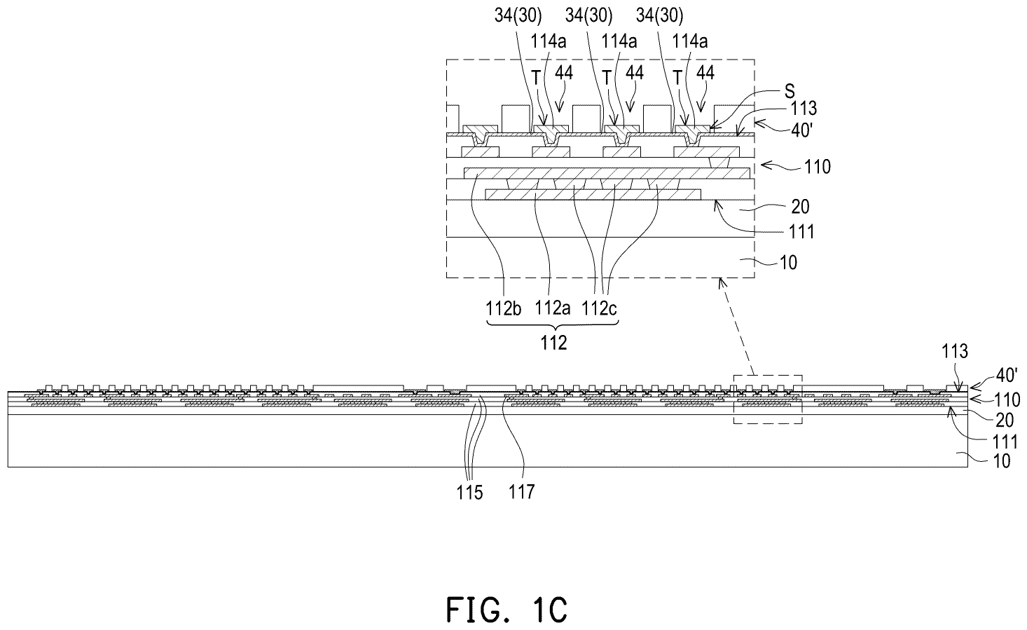

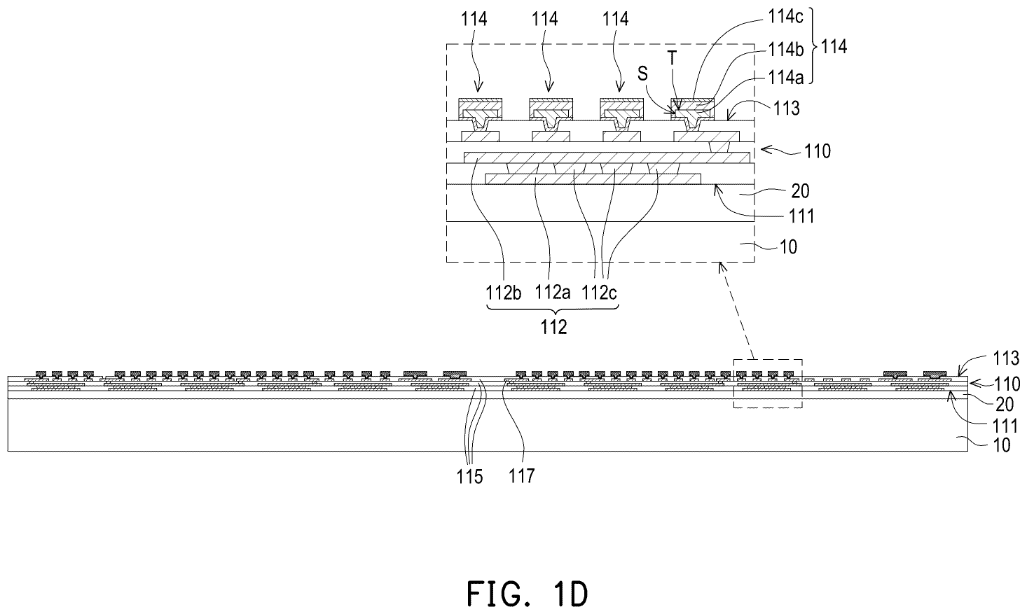

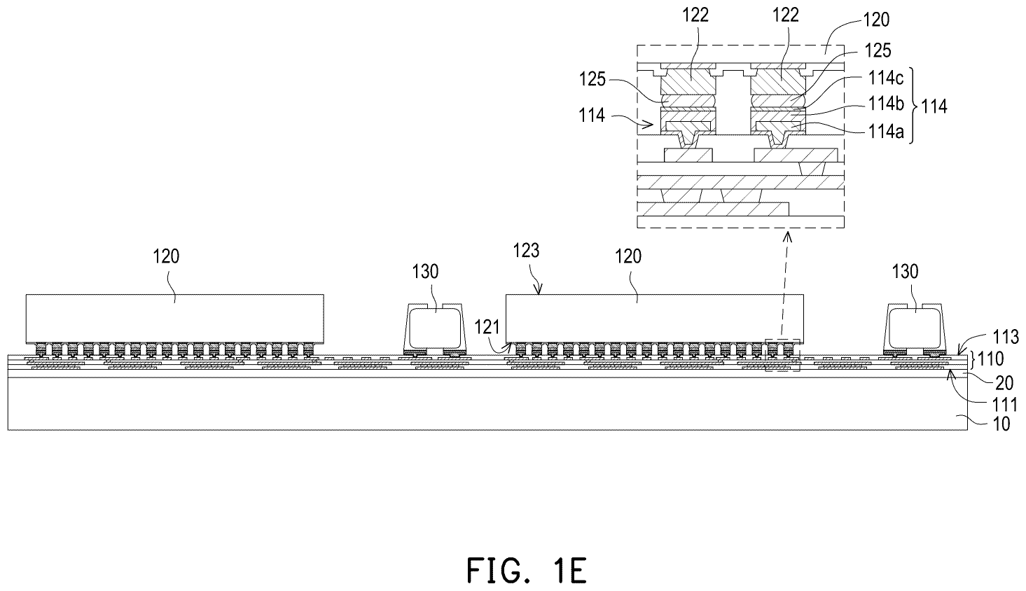

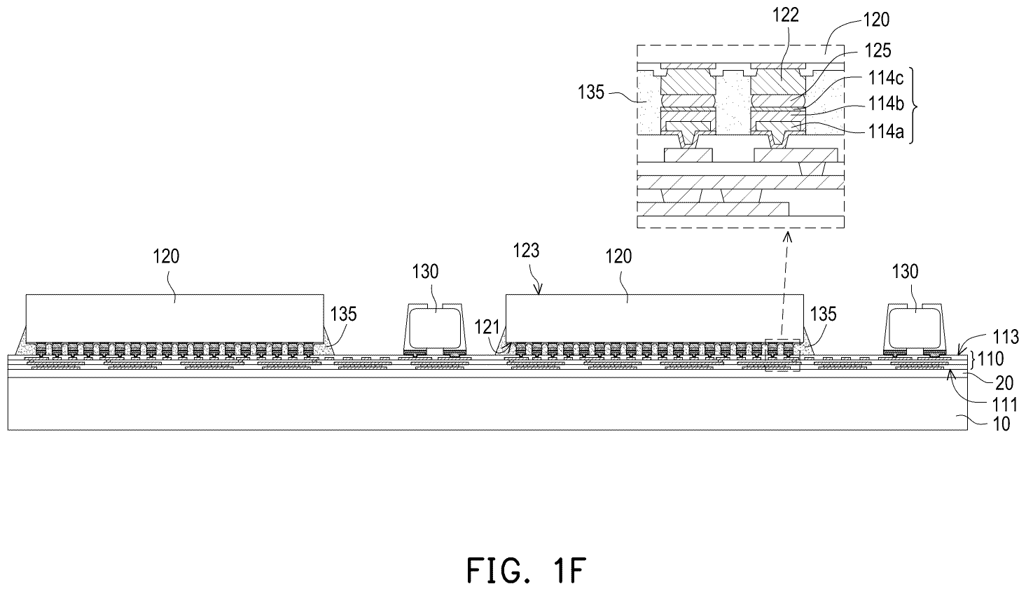

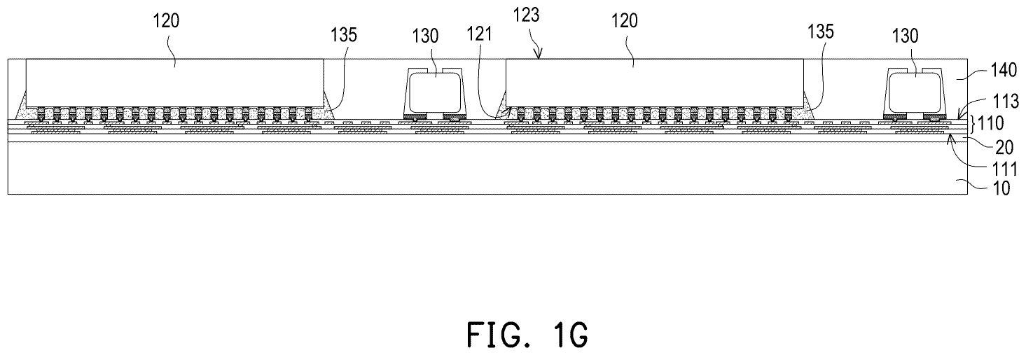

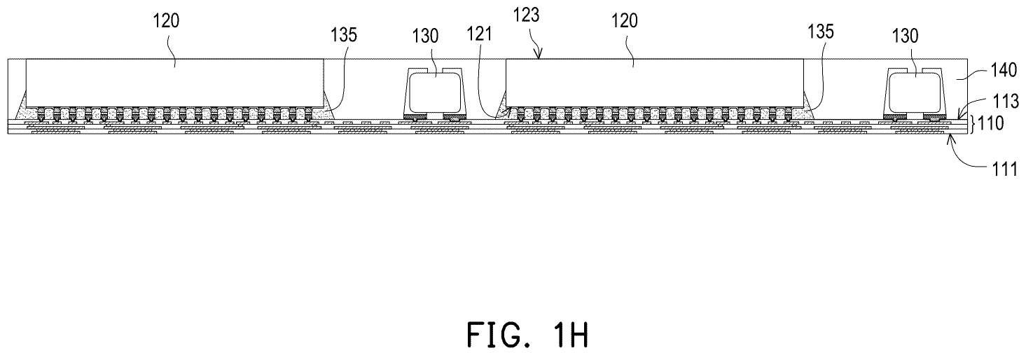

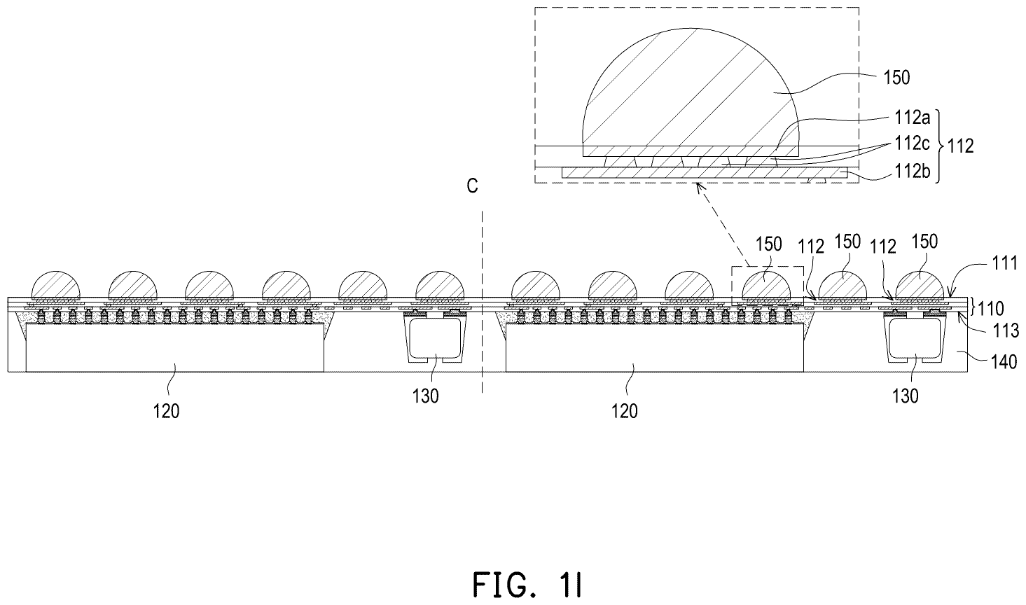

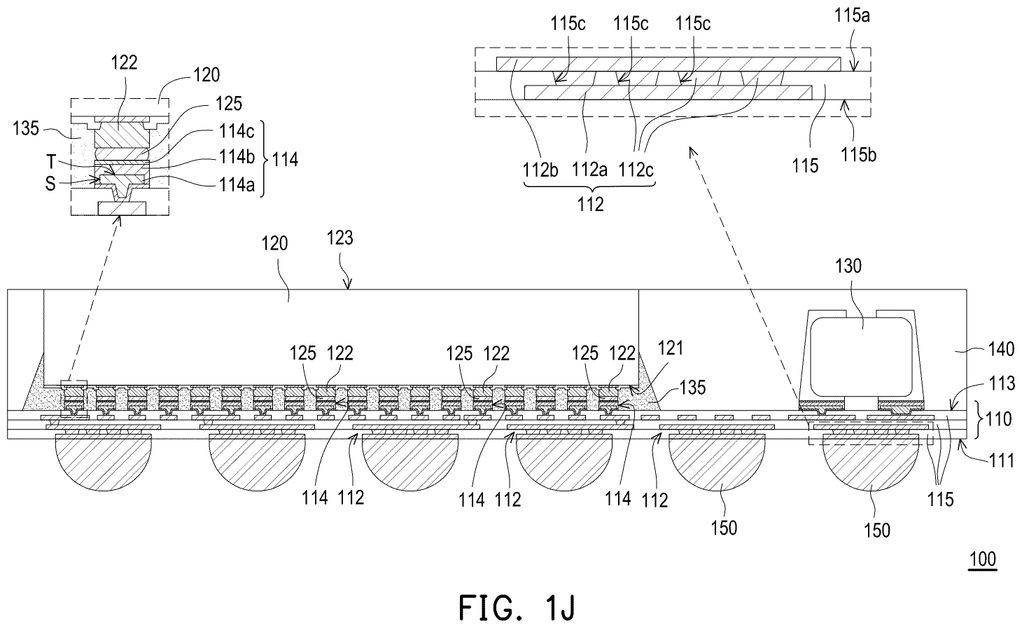

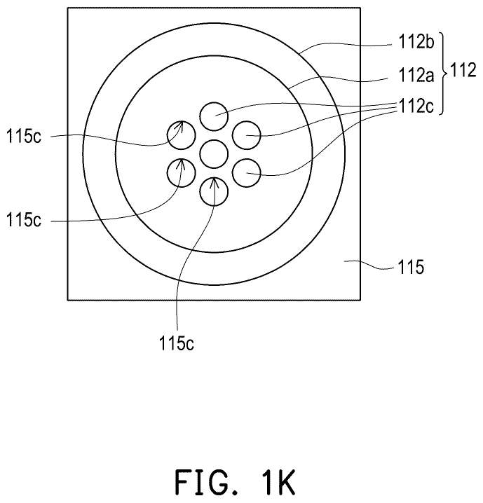

FIG. 1A to FIG. 1J are schematic cross-sectional views of a manufacturing method of a semiconductor package structure according to an embodiment of the disclosure. FIG. 1K is a top view of a first connector in FIG. 1J.

According to the manufacturing method of the semiconductor package structure of this embodiment, first, referring to FIG. 1A, a carrier board 10 and a redistribution structure layer 110 formed on the carrier board 10 are provided. In detail, first, the carrier board 10 is provided, in which the carrier board 10 may be, for example, a glass substrate, a silicon substrate, or a metal substrate, but the disclosure is not limited thereto. In an embodiment, the material of the carrier board 10 is not particularly limited, as long as the carrier board 10 is suitable for carrying the film layer formed thereon or the components disposed thereon.

Next, referring to FIG. 1A again, a release layer 20 is formed on the carrier board 10, in which the release layer 20 may directly cover a surface 11 of the carrier board 10. In an embodiment, the release layer 20 may be formed by coating, but the disclosure is not limited thereto.

Next, referring to FIG. 1A again, the redistribution structure layer 110 is formed on the release layer 20, in which the release layer 20 is located between the redistribution structure layer 110 and the carrier board 10. In detail, the redistribution structure layer 110 has a first side 111 and a second side 113 opposite to each other, and includes a plurality of first connectors 112 located on the first side 111. The first side 111 of the redistribution structure layer 110 is disposed on the carrier board 10, and the first side 111 directly contacts the release layer 20. Each first connector 112 includes a connecting pad 112a, a soldering pad 112b, and a plurality of conductive blind holes 112c located between the connecting pad 112a and the soldering pad 112b. In particular, the conductive blind holes 112c are disposed separately from each other and connected to the connecting pad 112a and the soldering pad 112b. The conductive blind holes 112c in each first connector 112 may be regarded as a kind of cluster vias, that is, one wide via hole is divided into multiple narrow via holes.

Furthermore, in the embodiment, the redistribution structure layer 110 may further include a dielectric layer 115 and a conductive layer 117, in which the dielectric layer 115 and the conductive layer 117 are alternately stacked, and the conductive layer 117 may form corresponding circuits (such as redistributed thin circuits), the connecting pad 112a, and the soldering pad 112b. The layout design of the circuit may be adjusted according to requirements, and the disclosure is not limited thereto. For example, in the circuit of the redistribution structure layer 110, portions not connected in the drawing may be electrically connected through other not-shown portions and/or other conductive components.

Taking the dielectric layer 115 closest to the first side 111 of the redistribution structure layer 110 as an example, referring to FIG. 1A together with FIG. 1K, the dielectric layer 115 may have a first surface 115a and a second surface 115b opposite to each other and multiple openings 115c. The soldering pad 112b of each first connector 112 is disposed on the first surface 115a, and the connecting pad 112a of each first connector 112 is embedded in the second surface 115b. The openings 115c are separated from each other and extend from the first surface 115a toward the second surface 115b to expose a portion of the connecting pads 112a. The conductive blind hole 112c of each first connector 112 is located in the opening 115c and is electrically connected to the soldering pad 112b and the connecting pad 112a of each first connector 112. In an embodiment, the conductive blind hole 112c may be filled in the opening 115c by electroplating or sputtering using the characteristics of the liquid to form a flat topography. Viewed from a top view, the shape of each opening 115c of the dielectric layer 115 is, for example, a circle, an ellipse, or a polygon. In other words, the shape of the conductive blind hole 112c formed in each opening 115c is also, for example, a circle, an ellipse, or a polygon. In an example, the shapes of the conductive blind holes 112c may be exactly the same, partly the same, or be completely different, and the disclosure is not limited thereto. In an embodiment, the orthographic projection area of the soldering pad 112b of each first connector 112 on the dielectric layer 115 may be overlapped with and may be larger than the orthographic projection area of the connecting pad 112a on the dielectric layer 115.

This embodiment uses the design of providing the multiple openings 115c on the dielectric layer 115 to reduce the surface unevenness of the soldering pad 112b, and also indirectly reduces the unevenness of the subsequent dielectric layer and metal layer formed on the soldering pad 112b, thereby the yield of post-process is provided. Furthermore, in this embodiment, there are a plurality of conductive blind holes 112c connecting the connecting pad 112a and the soldering pad 112b, in which the quantity of the conductive blind holes 112c of each first connector 112 is two or more. Therefore, compared with the related art where only one conductive blind hole is connected between a solder ball connecting pad and a soldering pad, in addition to increasing the filling capacity of holes, this embodiment may reduce the unevenness of the subsequent structure layer formed on the soldering pad 112b, the flatness is improved, thereby the yield of subsequent film layers formed thereon can be improved, especially the yield of manufacturing fine lines in the redistribution structure layer 110, so that the redistribution structure layer 110 can have better structural flatness.

Furthermore, since the design of each first connector 112 including the plurality of conductive blind holes 112c can make the dielectric layer 115 relatively flat, that is, the topography is smooth, a wider process window (process tolerance) can be obtained. In addition, the redistribution structure layer 110 of this embodiment may be formed by commonly used semiconductor processes (for example, deposition processes, photolithography processes, and/or etching processes), so details will not be described here. In an embodiment, the redistribution structure layer 110 may be, for example, a fan-out redistribution layer, but the disclosure is not limited thereto.

Next, referring to FIG. 1B, a seed layer 30 is formed on the second side 113 of the redistribution structure layer 110, wherein the seed layer 30 is formed by, for example, a sputtering process in a physical vapor deposition (PVD) method, and the material of the seed layer 30 is, for example, a titanium/copper stacked layer, but the disclosure is not limited thereto. Next, a patterned photoresist layer 40 is formed on the seed layer 30. The patterned photoresist layer 40 has a plurality of first openings 42, and the first openings 42 respectively expose a first portion 32 of the seed layer 30. Next, using the patterned photoresist layer 40 as an electroplating mask, by electroplating, a plurality of chip connecting pads 114a are formed on the first portion 32 of the seed layer 30 exposed by the first openings 42, in which each first opening 42 exposes a top surface T of each chip connecting pad 114a. Here, each chip connecting pad 114a has the top surface T and a surrounding surface S connected to the top surface T, and the surrounding surface S of each chip connecting pad 114a directly contacts the inner wall of the corresponding first opening 42. That is to say, there is no gap between the surrounding surface S of each chip connecting pad 114a and the inner wall of the corresponding first opening 42. In an embodiment, the material of the chip connecting pad 114a is, for example, copper, but the disclosure is not limited thereto.

Next, referring to FIG. 1B together with FIG. 1C, a portion of the patterned photoresist layer 40 located around each chip connecting pad 114a is removed to form a photoresist layer 40′ having a plurality of second openings 44. Each second opening 44 exposes the top surface T of each chip connecting pad 114 a, the surrounding surface S connected to the top surface T, and a second portion 34 of the seed layer 30. That is to say, the surrounding surface S of each chip connecting pad 114a is spaced apart from the inner wall of the corresponding second opening 44.

In an embodiment, the method for removing the portion of the patterned photoresist layer 40 located around each chip connecting pad 114a is, for example, an exposure process and a development process, which means to form the photoresist layer 40′ having the larger second opening 44 by re-exposure and re-development. On the other hand, the process of exposure and development steps are performed again with the photomask with a larger opening. In another embodiment, the method for removing the portion of the patterned photoresist layer 40 located around each chip connecting pad 114a is, for example, an over-development process, which means to form the photoresist layer 40′ having the larger second opening 44 through over-development. In still another embodiment, the method for removing the portion of the patterned photoresist layer 40 located around each chip connecting pad 114a is, for example, a plasma dry etching process, which means to form the photoresist layer 40′ having the larger second opening 44 through plasma dry etching.

Next, referring to FIG. 1C together with FIG. 1D, using the photoresist layer 40′ as an electroplating mask, by electroplating, a nickel layer 114b is formed on the top surface T and the surrounding surface S of each chip connecting pad 114a and the second portion 34 of the seed layer 30 exposed by each second opening 44. In an embodiment, the thickness of the nickel layer 114b on the surrounding surface S may be less than or equal to the thickness on the top surface T, and the thickness of the electroplated nickel layer may be adjusted according to requirements. Immediately afterward, the photoresist layer 40′ is used as an electroplating mask again, by electroplating, a gold layer 114c is formed on the nickel layer 114b. At this time, the gold layer 114c is formed only on the nickel layer 114b located on the top surface T of the chip connecting pad 114a. That is to say, the gold layer 114c does not cover the surrounding surface of the nickel layer 114b, and the gold layer 114c and the nickel layer 114b are not disposed in a conformal manner. Afterward, the photoresist layer 40′ and the seed layer 30 therebelow are removed, and the second side 113 of the redistribution structure layer 110 is exposed.

Here, each chip connecting pad 114a, the nickel layer 114b covering the top surface T and the surrounding surface S of the chip connecting pad 114a, and the gold layer 114c covering the nickel layer 114b located on the top surface T of the chip connecting pad 114a may define a second connector 114. The top surface T and the surrounding surface S of the chip connecting pad 114a are directly covered by the nickel layer 114b, and the gold layer 114c is limited to the nickel layer 114b located on the top surface T. In short, the redistribution structure layer 110 of this embodiment has the first connector 112 located on the first side 111 and the second connector 114 located on the second side 113. In an embodiment, the disposition density of the second connectors 114 is, for example, greater than the disposition density of the first connectors 112. That is to say, within a unit area, the quantity of the second connectors 114 may be greater than the quantity of the first connectors 112. In an embodiment, the second connector 114 may be regarded as a fine pitch flip chip bonding pad.

Since this embodiment only uses one layer of physical vapor deposition (PVD) (sputtering) and one layer of photoresist layer, and then the second connector 114 is formed, thereby a cost-saving, simple, and short-cycle manufacturing process is provided.

Next, referring to FIG. 1E, multiple solders 125 are disposed on at least one chip (two chips 120 are schematically shown), and the chip 120 is disposed on the second side 113 of the redistribution structure layer 110, in which the chip 120 is electrically connected to the second connector 114 of the redistribution structure layer 110 through the solder 125. In detail, the chip 120 has an active surface 121 and a back 123 opposite to each other, in which the active surface 121 faces the second side 113 of the redistribution structure layer 110. In an embodiment, a plurality of third connectors 122 are formed on the active surface 121 of the chip 120, in which the multiple solders 125 are respectively located between the third connector 122 and the second connector 114 of the redistribution structure layer 110. That is to say, the chip 120 is disposed on the second connector 114 of the redistribution structure layer 110 in a flip chip bonding manner. In an embodiment, the material of the third connector 122 includes nickel or copper/nickel, but the disclosure is not limited thereto. In an embodiment, the third connector 122 and the solder 125 may define a bump C2, such as a copper/tin-silver micro-bump or a copper/nickel/tin-silver micro-bumps, or a bump C4, such as a nickel/tin-silver micro-bump, but the disclosure is not limited thereto.

Nickel is usually used as a barrier metal for solder bonding due to the material having characteristics such as alloy inertness and high melting point. The nickel layer 114b of the second connector 114 can reduce the rate of the intermetallic compound (IMC) generated by the reaction between copper and tin during high-temperature reflow, and can prevent mutual diffusion between copper/tin (that is, the chip connecting pad 114a and the solder 125) during the reflow process and reliability test. Furthermore, since there is the nickel layer 114b and the gold layer 114c between the solder 125 and the chip connecting pad 114a of the second connector 114, in which the nickel layer 114b covers the top surface T and the surrounding surface S of the chip connecting pad 114a, and the gold layer 114c covers the nickel layer 114b located on the top surface T of the chip connecting pad 114a, the situation that tin (that is, the solder 125) flowing to the side surface of the second connector 114 at high temperatures which causes the volume of the solder 125 on the surface of the gold layer 114c to be insufficient to affect the yield of flip chip bonding can be prevented. The nickel layer 114b covering the top surface T and the surrounding surface S of the chip connecting pad 114a can also effectively suppress the Galvanic effect. Suppress the Galvanic effect between Ni/Cu during PVD Cu etching process to cause severe Cu undercut, because Ni/Cu interface won't be exposed by current invention. In addition, the geometric structure design of the second connector 114 can also reduce the risk of solder joint breakage after a high temperature storage (HTS) test. In other words, the design of the second connector 114 may be applied to multiple high-temperature procedures. In an embodiment, due to the geometric structure design of the second connector 114, the spacing between the solders 125 and the spacing between the third connectors 122 can be further reduced.

Next, referring to FIG. 1E again, optionally, at least one passive component (two passive components 130 are schematically shown) is disposed on the second side 113 of the redistribution structure layer 110, in which the passive component 130 is electrically connected to the redistribution structure layer 110. In an embodiment, the passive component 130 is, for example, an inductor, a capacitor, or a resistor, but the disclosure is not limited thereto.

Next, please refer to FIG. 1F. In order to effectively protect the electrical connection relationship between the chip 120 and the redistribution structure layer 110, an underfill 135 may be formed between the chip 120 and the second connector 114 of the redistribution structure layer 110, and covers the second connector 114, the solder 125, and the third connector 122. In an embodiment, the material of the underfill 135 may be, for example, resin, epoxy resin, or molding compound, but the disclosure is not limited thereto.

Next, referring to FIG. 1G, an encapsulant 140 is formed on the second side 113 of the redistribution structure layer 110, in which the encapsulant 140 at least covers the chip 120 and the second side 113 of the redistribution structure layer 110. Here, the encapsulant 140 covers the chip 120, the passive component 130, the underfill 135, and the second side 113 of the redistribution structure layer 110, and may optionally expose the back 123 of the chip 120. In other words, the passive component 130 is embedded in the encapsulant 140. In an embodiment, the material of the encapsulant 140 is, for example, epoxy molding compound (EMC), in which the encapsulant 140 is formed by, for example, a molding process, but the disclosure is not limited thereto.

For example, a molding material may be formed on the redistribution structure layer 110, and after the molding material is cured, a planarization process may be performed to form the encapsulant 140. After the planarization process, the encapsulant 140 may expose the back 123 of the chip 120. In other words, the surface of the encapsulant 140 relatively far away from the redistribution structure layer 110 may be coplanar with the back 123 of the chip 120, thereby heat dissipation of the chip 120 is effectively facilitated, and a better heat dissipation effect is achieved. In an embodiment, the planarization process is, for example, a grinding process. In another embodiment, the encapsulant 140 may also cover the back 123 of the chip 120, which still belongs to the scope of protection of the disclosure.

Next, please refer to FIG. 1G and FIG. 1H at the same time to peel off the release layer 20 to remove the carrier board 10 and expose the first side 111 of the redistribution structure layer 110.

After that, please refer to FIG. 1H together with FIG. 1I. The structure shown in FIG. 1H is flipped upside-down, and then by appropriate methods, such as ball mounting process, multiple solder balls 150 are formed on the first side 111 of the redistribution structure layer 110 and are electrically connected to the redistribution structure layer 110, in which the solder balls 150 are respectively connected to the connecting pads 112a of the respective first connectors 112. In an embodiment, the material of the solder ball 150 is, for example, tin, but the disclosure is not limited thereto.

Finally, referring to FIG. 1I together with FIG. 1J, the dicing and singulation process is performed along a scribe line C to dice the redistribution structure layer 110 and the encapsulant 140 to form multiple semiconductor package structures 100 as shown in FIG. 1J. At this point, the manufacturing of the semiconductor package structure 100 is completed.

Structurally, referring to FIG. 1J again, the semiconductor package structure 100 includes the redistribution structure layer 110, the chip 120, the encapsulant 140, and the solder ball 150. The redistribution structure layer 110 has the first side 111 and the second side 113 opposite to each other, and includes the first connectors 112 located on the first side 111. Each first connector 112 includes the connecting pad 112a, the soldering pad 112b, and the plurality of conductive blind holes 112c located between the connecting pad 112a and the soldering pad 112b. The conductive blind holes 112c are disposed separately from each other and connected to the connecting pad 112a and the soldering pad 112b. The chip 120 is disposed on the second side 113 of the redistribution structure layer 110 and is electrically connected to the redistribution structure layer 110. The encapsulant 140 is disposed on the second side 113 of the redistribution structure layer 110, and at least covers the chip 120 and the second side 113 of the redistribution structure layer 110. The solder ball 150 is disposed on the first side 111 of the redistribution structure layer 110 and is electrically connected to the redistribution structure layer 110. The solder balls 150 are respectively connected to the connecting pads 112a of the respective first connectors 112.

Specifically, in this embodiment, the redistribution structure layer 110 further includes the second connectors 114 located on the second side 113, in which the chip 120 is electrically connected to the second connectors 114. Each second connector 114 includes the chip connecting pad 114a, the nickel layer 114b, and the gold layer 114c. The chip connecting pad 114a has the top surface T and the surrounding surface S connected to the top surface T. The nickel layer 114b covers the top surface T and the surrounding surface S of the chip connecting pad 114a, and the gold layer 114c covers the nickel layer 114b located on the top surface T of the chip connecting pad 114a. In an embodiment, the disposition density of the second connectors 114 is, for example, greater than the disposition density of the first connectors 112. That is to say, within the unit area, the quantity of the second connectors 114 is greater than the quantity of the first connectors 112.

Please refer to FIG. 1J together with FIG. 1K. The redistribution structure layer 110 of this embodiment further includes the dielectric layer 115. The dielectric layer 115, which is relatively far away from the chip 120, has the first surface 115a and the second surface 115b opposite to each other and the multiple openings 115c. The soldering pad 112b of each first connector 112 is disposed on the first surface, and the connecting pad 112a of each first connector 112 is embedded in the second surface 115b. The openings 115c are separated from each other and extend from the first surface 115a toward the second surface 115b to expose the portion of the connecting pad 112a. The conductive blind hole 112c of each first connector 112 is located in the opening 115c and is electrically connected to the soldering pad 112b and the connecting pad 112a of each first connector 112. In an embodiment, the quantity of the conductive blind holes 112c of each first connector 112 is, for example, two or more. Viewed from a top view, the shape of each opening 115c of the dielectric layer 115 is, for example, a circle, an ellipse, or a polygon. The orthographic projection area of the soldering pad 112b of each first connector 112 on the dielectric layer 115 is overlapped with and is larger than the orthographic projection area of the connecting pad 112a on the dielectric layer 115. In an embodiment, the redistribution structure layer 110 may be, for example, a fan-out redistribution structure layer.

Furthermore, the chip 120 of this embodiment has the active surface 121 and the back 123 opposite to each other, in which the active surface 121 of the chip 120 is parallel to the redistribution structure layer 110, which means that the redistribution structure layer 110 has better structural flatness. The active surface 121 faces the second side 113 of the redistribution structure layer 110, and the encapsulant 140 is exposed outside the back 123, thereby heat dissipation of the chip 120 is facilitated. The semiconductor package structure 100 further includes the plurality of third connectors 122 disposed between the chip 120 and the second connector 114 of the redistribution structure layer 110. In an embodiment, the material of each third connector 122 includes nickel or copper/nickel, but the disclosure is not limited thereto. In addition, the semiconductor package structure 100 of this embodiment further includes the solder 125, in which the chip 120 is electrically connected to the second connector 114 of the redistribution structure layer 110 through the solder 125. That is to say, the chip 120 of this embodiment is electrically connected to the redistribution structure layer 110 through the flip chip bonding manner. In an embodiment, the third connector 122 and the solder 125 may define the bump C2, such as a copper/tin-silver micro-bump or a copper/nickel/tin-silver micro-bump, or the bump C4, such as a nickel/tin-silver micro-bump, but the disclosure is not limited thereto.

Furthermore, in the redistribution structure layer 110 of this embodiment, for the second connector 114, the design of each first connector 112 including the plurality of conductive blind holes 112c can reduce the unevenness of the subsequent structure layer formed on the soldering pad 112b, and the flatness can be improved. Since the design of each first connector 112 including the multiple conductive blind holes 112c can make the subsequent structure layer formed on the soldering pad 112b relatively flat, that is, the topography is smooth, the coplanarity between the second connectors 114 is improved and the bonding yield of the solders 125 is improved. Furthermore, since the design of each first connector 112 including the plurality of conductive blind holes 112c reduce the unevenness of the subsequent structure layer formed on the soldering pad 112b, thereby the risk of line interruption and short circuit during the flip chip bonding process of the chip 120 is reduced. In addition, the design of each first connector 112 including the plurality of conductive blind holes 112c can improve the yield of the semiconductor package structure 100. In addition, the finer redistributed thin circuits in the redistribution structure layer 110 are usually disposed close to the active surface 121 of the chip 120, so the flattened dielectric layer 115 above the first connector 112 helps the finer redistributed thin circuits pass through the first connector 112.

In addition, the nickel layer 114b of the second connector 114 can reduce the rate of the intermetallic compound (IMC) generated by the reaction between copper and tin during high-temperature reflow, and can prevent mutual diffusion between copper/tin (that is, chip connecting pad 114a and the solder 125) during the reflow process and reliability test. Furthermore, since there is the nickel layer 114b and the gold layer 114c between the solder 125 and the chip connecting pad 114a of the second connector 114, in which the nickel layer 114b covers the top surface T and the surrounding surface S of the chip connecting pad 114a, and the gold layer 114c covers the nickel layer 114b located on the top surface T of the chip connecting pad 114a, the situation that tin (that is, the solder 125) flowing to the side surface of the second connector 114 at high temperatures which causes the volume of the solder 125 on the surface of the gold layer 114c to be insufficient to affect the yield of flip chip bonding can be prevented. The nickel layer 114b covering the top surface T and the surrounding surface S of the chip connecting pad 114a can also effectively suppress the Galvanic effect. Suppress the Galvanic effect between Ni/Cu during PVD Cu etching process to cause severe Cu undercut, because Ni/Cu interface won't be exposed by current invention. In an embodiment, due to the geometric structure design of the second connector 114, the spacing between the solders 125 and the spacing between the third connectors 122 can be further reduced.

Furthermore, in order to effectively protect the electrical connection relationship between the chip 120 and the redistribution structure layer 110, the semiconductor package structure 100 of this embodiment may further include the underfill 135 disposed between the chip 120 and the second connector 114 of the redistribution structure layer 110 and covering the second connector 114, the solder 125, and the third connector 122. In addition, the semiconductor package structure 100 of this embodiment may optionally include the passive component 130 disposed on the second side 113 of the redistribution structure layer 110 and is electrically connected to the redistribution structure layer 110, in which the encapsulant 140 also completely covers the passive component 130. Here, the encapsulant 140 directly contacts the second side 113 of the redistribution structure layer 110, covers the chip 120, the underfill 135, and the passive component 130, and exposes the back 123 of the chip 120, thereby heat dissipation is facilitated. In an embodiment, the side of the encapsulant 140 relatively far away from the redistribution structure layer 110 may be flush with the back 123 of the chip 120, that is, coplanar with the back 123 of the chip 120, which facilitates the subsequent connection of the semiconductor package structure 100 with other packages. In summary, in the semiconductor package structure of the disclosure, the first connector

of the redistribution structure layer includes the connecting pad, the soldering pad, and the plurality of conductive blind holes located between the connecting pad and the soldering pad, in which the conductive blind holes are disposed separately from each other and connected to the connecting pad and the soldering pad. Through the manner of the conductive blind holes connecting the connecting pad and the soldering pad, the subsequent film layer formed thereon can be relatively flat, so the overall redistribution structure layer can have better structural flatness, thereby the semiconductor package structure of the disclosure can have better structural reliability.

Although the disclosure has been disclosed above through embodiments, the embodiments are not intended to limit the disclosure. Persons with ordinary knowledge in the relevant technical field may make some changes and modifications without departing from the spirit and scope of the disclosure. Therefore, the protection scope of the disclosure shall be determined by the appended claims.

What is claimed is:

1. A semiconductor package structure, comprising:
a redistribution structure layer having a first side and a second side opposite to each other, and comprising a plurality of first connectors located on the first side, wherein each of the first connectors comprises a connecting pad, a soldering pad, and a plurality of conductive blind holes located between the connecting pad and the soldering pad, and the conductive blind holes are disposed separately from each other and connected to the connecting pad and the soldering pad;
at least one chip disposed on the second side of the redistribution structure layer and electrically connected to the redistribution structure layer;
an encapsulant disposed on the second side of the redistribution structure layer and at least covering the at least one chip and the second side of the redistribution structure layer; and
a plurality of solder balls disposed on the first side of the redistribution structure layer and electrically connected to the redistribution structure layer, wherein the solder balls are respectively connected to the connecting pads of the respective first connectors.

2. The semiconductor package structure as claimed in claim 1, wherein the at least one chip has at least one active surface and at least one back opposite to each other, the at least one active surface faces the second side of the redistribution structure layer, and the encapsulant is exposed outside the at least one back.

3. The semiconductor package structure as claimed in claim 1, wherein the redistribution structure layer further comprises a plurality of second connectors located on the second side, and the at least one chip is electrically connected to the second connectors.

4. The semiconductor package structure as claimed in claim 3, wherein each of the second connectors comprises a chip connecting pad, a nickel layer, and a gold layer, the chip connecting pad has a top surface and a surrounding surface connected to the top surface, the nickel layer covers the top surface and the surrounding surface of the chip connecting pad, and the gold layer covers the nickel layer on the top surface of the chip connecting pad.

5. The semiconductor package structure as claimed in claim 3, wherein a disposition density of the second connectors is greater than a disposition density of the first connectors.

6. The semiconductor package structure as claimed in claim 3, further comprising:
a plurality of third connectors disposed between the at least one chip and the second connectors of the redistribution structure layer; and
a plurality of solders respectively located between the third connectors and the second connectors of the redistribution structure layer.

7. The semiconductor package structure as claimed in claim 6, wherein each of the third connectors and each of the solders define a copper/tin-silver micro-bump, a copper/nickel/tin-silver micro-bump, or a nickel/tin-silver micro-bump.

8. The semiconductor package structure as claimed in claim 6, further comprising:
an underfill disposed between the at least one chip and the second connectors of the redistribution structure layer and covering the second connectors and the third connectors.

9. The semiconductor package structure as claimed in claim 1, further comprising:
at least one passive component disposed on the second side of the redistribution structure layer and electrically connected to the redistribution structure layer, wherein the encapsulant covers the at least one passive component.

10. The semiconductor package structure as claimed in claim 1, wherein the redistribution structure layer further comprises a dielectric layer, the dielectric layer has a first surface and a second surface opposite to each other and a plurality of openings, the soldering pad of each of the first connectors is disposed on the first surface, the connecting pad of each of the first connectors is embedded in the second surface, the openings are separated from each other and extend from the first surface toward the second surface to expose a portion of the connecting pads, the conductive blind holes of the respective first connectors are respectively located in the openings and electrically connected to the soldering pads and the connecting pads of the respective first connectors.

11. The semiconductor package structure as claimed in claim 10, wherein viewed from above, a shape of each of the openings of the dielectric layer comprises a circle, an ellipse, or a polygon.

12. The semiconductor package structure as claimed in claim 10, wherein an orthographic projection area of the soldering pad of each of the first connectors on the dielectric layer is overlapped with and larger than an orthographic projection area of the connecting pad on the dielectric layer.

13. The semiconductor package structure as claimed in claim 1, wherein at least one active surface of the at least one chip is parallel to the redistribution structure layer.

14. The semiconductor package structure as claimed in claim 1, wherein a quantity of the conductive blind holes of each of the first connectors is two or more.

15. The semiconductor package structure as claimed in claim 1, wherein the redistribution structure layer comprises a fan-out redistribution structure layer.

16. A manufacturing method of a semiconductor package structure, comprising:
providing a carrier board and a redistribution structure layer formed on the carrier board, wherein the redistribution structure layer has a first side and a second side opposite to each other and comprises a plurality of first connectors located on the first side, the first side of the redistribution structure layer is disposed on the carrier board, each of the first connectors comprises a connecting pad, a soldering pad, and a plurality of conductive blind holes located between the connecting pad and the soldering pad, the conductive blind holes are disposed separately from each other and connected to the connecting pad and the soldering pad;
disposing at least one chip on the second side of the redistribution structure layer, wherein the at least one chip is electrically connected to the redistribution structure layer;
forming an encapsulant on the second side of the redistribution structure layer, wherein the encapsulant at least covers the at least one chip and the second side of the redistribution structure layer;
removing the carrier board to expose the first side of the redistribution structure layer; and
forming a plurality of solder balls on the first side of the redistribution structure layer, wherein the solder balls are electrically connected to the redistribution structure layer, and the solder balls are respectively connected to the connecting pads of the respective first connectors.

17. The manufacturing method of the semiconductor package structure as claimed in claim 16, before disposing the at least one chip on the second side of the redistribution structure layer, further comprising:
forming a seed layer on the second side of the redistribution structure layer;
forming a patterned photoresist layer on the seed layer, wherein the patterned photoresist layer has a plurality of first openings, and the first openings respectively expose a first portion of the seed layer;
using the patterned photoresist layer as an electroplating mask, and forming, by electroplating, a plurality of chip connecting pads on the first portion of the seed layer exposed by the first openings, wherein each of the first openings exposes a top surface of each of the chip connecting pads;
removing a portion of the patterned photoresist layer located around each of the chip connecting pads to form a photoresist layer having a plurality of second openings, wherein each of the second openings exposes the top surface of each of the chip connecting pads, a surrounding surface connected to the top surface, and a second portion of the seed layer;
using the photoresist layer as the electroplating mask, and forming, by electroplating, a nickel layer on the top surface and the surrounding surface of each of the chip connecting pads and the second portion of the seed layer exposed by the second opening;
using the photoresist layer as the electroplating mask, and forming, by electroplating, a gold layer on the nickel layer, wherein each of the chip connecting pads, the nickel layer covering the top surface and the surrounding surface of the chip connecting pad, and the gold layer covering the nickel layer located on the top surface of the chip connecting pad define a second connector; and
removing the photoresist layer and the seed layer therebelow.

18. The manufacturing method of the semiconductor package structure as claimed in claim 17, wherein methods for removing the portion of the patterned photoresist layer located around each of the chip connecting pads comprise an exposure process and a development process, an over-development process, or a plasma dry etching process.

19. The manufacturing method of the semiconductor package structure as claimed in claim 16, further comprising:
before forming the encapsulant on the second side of the redistribution structure layer, disposing at least one passive component on the second side of the redistribution structure layer, wherein the at least one passive component is electrically connected to the redistribution structure layer.

20. The manufacturing method of the semiconductor package structure as claimed in claim 16, wherein after forming the solder balls on the first side of the redistribution structure layer, performing a dicing and singulation process.
